(19) United States
(12) Patent Application Publication
(10) Pub. No.: US 2011/0284889 A1
(43) Pub. Date: Nov. 24, 2011

(54) ORGANIC EL PANEL AND METHOD FOR MANUFACTURING THE SAME

(75) Inventors: Kazuhiro Takeda, Tendo-shi (JP); Masanobu Akagi, Yamagata (JP); Kenichi Nagayama, Kanagawa (JP); Shin Kawami, Kanagawa (JP)

(73) Assignees: TOHOKU PIONEER CORPORATION, Yamagata (JP); PIONEER CORPORATION, Kawasaki-shi, Kanagawa (JP)

(21) Appl. No.: 13/145,712

(22) PCT Filed: Jan. 21, 2009
(86) PCT No.: PCT/JP2009/050862

§ 371 Date: Aug. 10, 2011

(51) Int. Cl. H01L 51/44; H01L 51/56

(52) U.S. Cl. 257/91; 438/29; 257/E51.018

(57) ABSTRACT

An organic EL panel forming light-emitting elements on a substrate includes lower electrode lines stripe-formed on the substrate, upper electrode lines stripe-formed so as to cross the lower electrode lines, an organic EL element laminating an organic layer including a light-emitting layer between the lower electrode lines and the upper electrode lines in the crossing part of the lower electrode lines and the upper electrode lines, extracting terminals electrically connected to the respective upper electrode lines and formed outside the light-emitting element forming area, a common organic layer formed so as to cover at least the overall side edges of the lower electrode lines within the light-emitting element forming area, and a cathode separator stripe-formed on the common organic layer within the light-emitting element forming area so as to insulate-segment the upper electrode lines with the end part extending to the extracting terminals.

### FIELD OF THE INVENTION

The present invention relates to an organic EL panel and the method of manufacturing the same.

### BACKGRAOUND OF THE INVENTION

An organic EL panel is provided with a single or a plurality of light emitting elements (pixels) composed of organic EL elements, capable of functioning as a display showing desired information, various types of light sources, illuminating devices, etc.by light driving or non-light driving each light emitting element. The organic EL element has a laminate structure wherein one of a pair of electrodes is defined as an anode while the other is defined as a cathode and an organic layer including a light-emitting layer is laminated between these electrodes, and a hole injected into the organic layer from the anode side and an electron injected into the organic layer from the cathode side are recombined in the light-emitting layer, thereby emitting light.

For example, the light emitting elements (pixels) of the organic EL panel may be arranged on a substrate in a dot matrix pattern. The organic EL panel in passive drive style provides common electrode lines corresponding to a plurality of the light emitting elements disposed in a row, and these electrode lines are planarly arranged in a stripe pattern, a plurality of electrode lines on the anode side and a plurality of electrode lines on the cathode side are crossed in multi-level and an organic EL element is provided on each of the crossing parts.

In order to form the organic EL panel in passive drive style, one electrode lines are stripe-formed on the substrate while stripe-shaped cathode separators are formed in the direction crossing the electrode lines, and the material of the other electrode lines are film-formed via these cathode separators, thereby the other electrode lines crossing the one electrode lines are insulate-segmented and formed in a striped shape.

The cathode separator formed as described above preferably has an inverted trapezoid cross-sectional shape (including trapezoid shape in which the upper side is longer than the lower side and T-shape). With this cross-sectional shape, an overhang portion can be formed such that the lateral face of the cathode separator has a downward tapered surface, and the electrode lines film-formed between the cathode separators are securely divided by the edge of the cathode separator such that the electrode lines are not connected over the cathode separator.

The patent literature 1 shown below discloses an organic EL device arranging a plurality of organic EL elements which laminate light-emitting organic layers between a hole injecting electrode (anode) and an electron injection-electrode (cathode), wherein an electronic insulating cathode separator having a patterned overhang portion is provided on an organic layer, and this cathode separator segments the electron injection-electrode formed on the organic layer for each electrode.

[Patent literature 1] Japanese patent No. 3540584

### SUMMARY OF THE INVENTION

In the organic EL panel described above, a plurality of light-emitting elements is formed on the substrate. An electrode line extracting terminal is formed outside the light-emitting element forming area, and the electrode lines formed by film forming the material of the electrode lines via the cathode separator are required to extend the end part to the aforementioned electrode line extracting terminal. For this purpose, the aforementioned cathode separator is required to be formed extending outside the light-emitting element forming area, and insulation segment of the electrode lines is required to be securely implemented up to the end part.

As described in the aforementioned prior art, although the cathode separator formed on the light-emitting element forming area is formed on the organic layer, when the cathode separator is extended to the outside of the light-emitting element forming area as described above, the cathode separator need be formed on the substrate with no organic layer formed for this extended portion. In this case, the material of the counterpart forming surface of the cathode separator is changed at the extended portion, thereby, even if the cathode separator firmly adheres to the organic layer, the end part of the cathode separator is subject to peel-off

An object of one or more embodiments of the present invention is to solve the problems described above. That is, an object of one or more embodiments of the present invention is to suppress the peel-off at the end part of a cathode separator, etc., when forming the cathode separator on the organic layer in order to form upper electrode lines so as to cross lower electrode lines formed on the substrate in an organic EL panel using a single organic EL element as a light-emitting element, a plurality of the light-emitting elements being formed on the substrate.

To attain the object, the organic EL panel and the method of manufacturing the same according to one or more embodiments of the present invention include the configuration of the following independent claims:

### [Claim 1]

An organic EL panel forming a plurality of light-emitting elements on a substrate, a single organic EL element being a light-emitting element, the organic EL panel including: a plurality of lower electrode lines stripe-formed on the substrate; a plurality of upper electrode lines stripe-formed so as to cross the lower electrode lines; an organic EL element laminating an organic layer including a light-emitting layer between the lower electrode lines and the upper electrode lines in the crossing part of the lower electrode lines and the upper electrode lines; a plurality of extracting terminals electrically connected to the respective upper electrode lines and formed outside a light-emitting element forming area on which the plurality of the light-emitting elements are formed on the substrate; a common organic layer formed so as to cover at least overall side edges of the lower electrode lines within the light-emitting element forming area; and a cathode separator stripe-formed on the common organic layer within the light-emitting element forming area so as to insulate-segment the upper electrode lines with an end part extending to the extracting terminals; wherein the cathode separator is arranged such that a width in a portion of a counterpart forming area formed outside the light-emitting element forming area is larger than a width in a portion of a counterpart forming area formed inside the light-emitting element forming area.

### [Claim 6]

A method of manufacturing an organic EL panel forming a plurality of light-emitting elements on a substrate, a single organic EL element being a light-emitting element, the method including: forming a plurality of stripe-shaped lower electrode lines on the substrate; forming a plurality of extracting terminals electrically connected to upper electrode lines on an outside of a light-emitting element forming area on which a plurality of the light-emitting elements on the substrate are formed; forming a common organic layer so as to cover all of the lower electrode lines within the light-emitting element forming area; stripe-forming a cathode separator insulate-segmenting the upper electrode lines so as to cross the lower electrode lines on the common organic layer within the light-emitting element forming area with an end part extending to the extracting terminals; forming an organic layer laminating an organic layer including a light-emitting layer on the common organic layer covering the lower electrode lines; and forming upper electrode lines so as to cross the lower electrode lines with the end part connected to the extracting terminals by film-forming a material of the upper electrode lines on the organic layer via the cathode separator; wherein in the forming the cathode separator, a lateral face of the cathode separator has a downward tapered surface, and a tapered angle of the tapered surface with respect to verticality is arranged such that an angle of a portion formed outside the light-emitting element forming area is smaller than an angle of a portion formed within the light-emitting element forming area.

### BRIEF DESCRIPTION OF THE DRAWINGS

FIG. 1 is a view illustrating an organic EL panel according to an embodiment of the present invention (plan view);

FIG. 2 is a cross-sectional view illustrating an organic EL panel according to an embodiment of the present invention (FIG. 2(a) is a cross-sectional view taken along the line A-A in FIG. 1 and FIG. 2(b) is a cross-sectional view taken along the line B-B in FIG. 1);

FIG. 3 is a cross-sectional view illustrating an organic EL panel according to an embodiment of the present invention (FIG. 3(a) is a cross-sectional view taken along the line C-C in FIG. 1 and FIG. 3(b) is a cross-sectional view taken along the line D-D in FIG. 1); and

FIG. 4 is a view illustrating a variation of an organic EL panel according to an embodiment of the present invention (plan view).

### DETAILED DESCRIPTION OF THE INVENTION

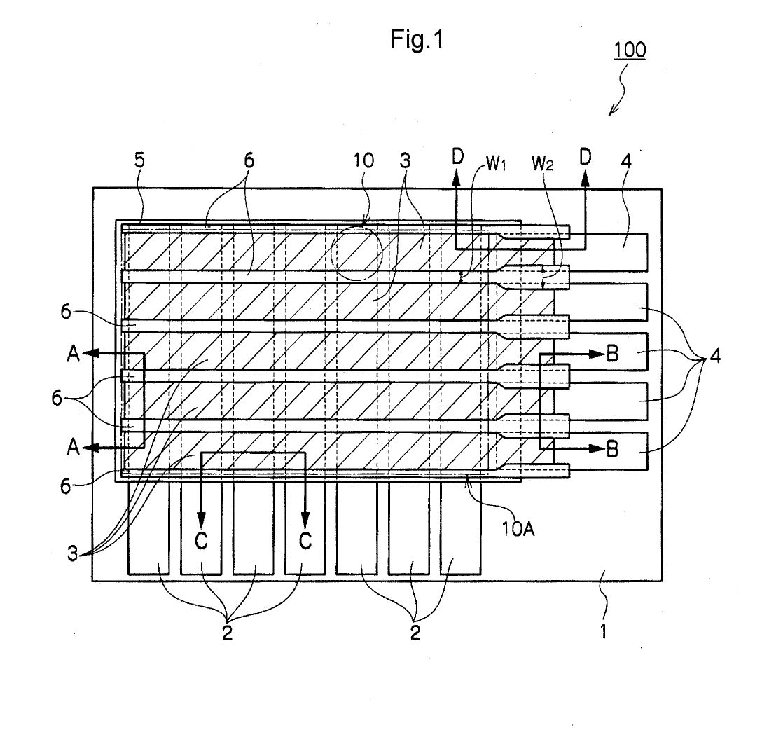

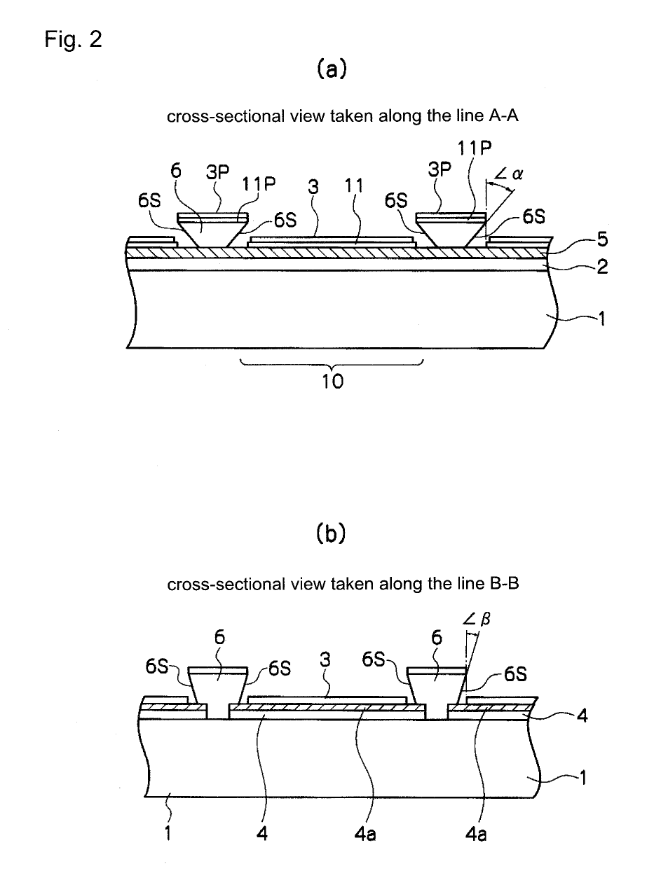

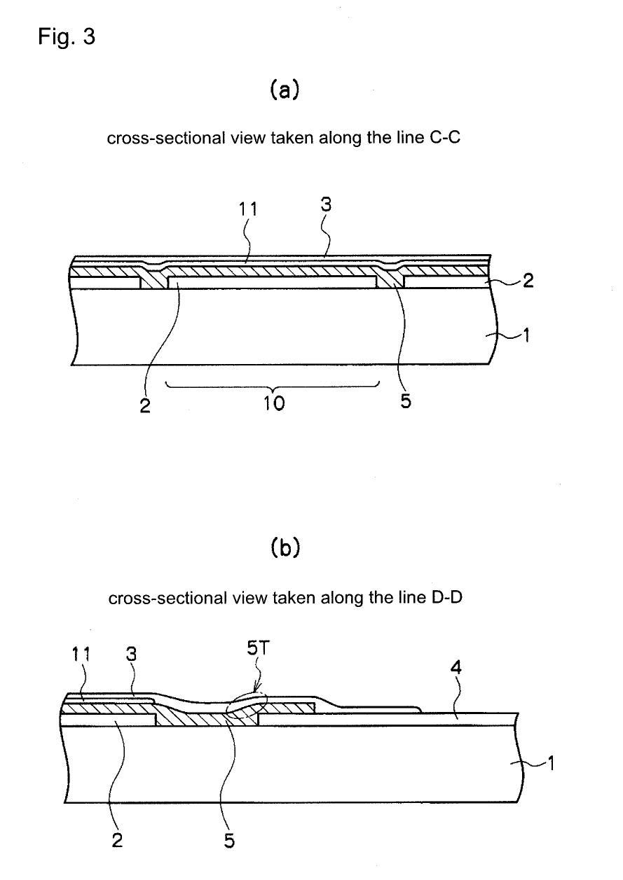

Hereinafter, an embodiment of the present invention is described with reference to the drawings. FIGS. 1 to 3 are views illustrating an organic EL panel according to one embodiment of the present invention. FIG. 1 is a plan view, FIG. 2(a) is a cross-sectional view taken along the line A-A in FIG. 1, FIG. 2(b) is a cross-sectional view taken along the line B-B in FIG. 1, FIG. 3(a) is a cross-sectional view taken along the line C-C in FIG. 1 and FIG. 3(b) is a cross-sectional view taken along the line D-D in FIG. 1.

An organic EL panel 100 forms a plurality of light emitting elements arranged on a substrate 1, and single organic EL element 10 functions as a single light emitting element. And, a region surrounded by the organic EL elements 10 on the most outer periphery along each side of the organic EL panel 100 is a light-emitting element forming area (organic EL element forming area) 10A.

And the organic EL panel 100 according to an embodiment of the present invention wherein a plurality of organic EL elements 10 are formed on the substrate 1, is principally configured with a lower electrode line 2, an upper electrode line 3, an extracting terminal 4, a common organic layer 5 and a cathode separator 6.

The lower electrode lines 2 are a plurality of electrode lines, which are formed on the substrate 1 in the stripe pattern. The upper electrode lines 3 are a plurality of electrode lines, which are stripe-formed so as to cross the lower electrode lines 2. In order to take out light from the substrate 1 side, lower electrode lines 2 must be transparent-electrodes while in order to take out light from the side opposite to the substrate 1, the upper electrode lines 3 must be transparent-electrodes. The organic EL elements 10 has organic layers 11 including a light-emitting layer, which are laminated between the lower electrode lines 2 and the upper electrode lines 3 at the crossing parts between the lower electrode lines 2 and the upper electrode lines 3 (see FIG. 2(a)).

A plurality of the extracting terminals 4 are formed in association with the upper electrode lines 3. The extracting terminals 4 are formed outside the light-emitting element forming area 10A on the substrate 1 on which a plurality of the light-emitting elements 10 are formed and are electrically connected to the upper electrode lines 3, respectively.

A common organic layer 5 is configured to cover at least the side edges of the lower electrode lines 2 within the whole light-emitting element forming area 10A. For example, the common organic layer 5 includes an insulating film covering the substrate 1 between the lower electrode lines 2 and only the side edges of the lower electrode lines 2 and a functional organic layer covering the whole surface including the upper face of the lower electrode lines 2, or specifically includes an organic layer, which has an insulating property in an area where no electric field is involved, and has a function of transporting a hole or an electron in an area where an electric field is involved.

Cathode separators 6 are formed in the stripe-shaped pattern on the common organic layer 5 within the light-emitting element forming area 10A in order to insulate-segment the upper electrode lines 2, with the end parts of the cathode separators 6 extending to the extracting terminals 4. That is, the cathode separators 6 are stripe-formed so as to cross the lower electrode lines 2, and the upper electrode lines 2 are formed between these cathode separators 6. The end parts of the cathode separators 6 are formed extending to the outside of the light-emitting element forming area 10A such that the upper electrode lines 3 securely reach the extracting terminals 4. As the cathode separators 6 function as shadow masks, when the organic layer 11 and the upper electrode lines 3 are film formed after the cathode separators 6 are formed, an organic layer material 11P and an upper electrode material 3P are laminated on the cathode separators 6 (see FIG. 2(a)).

Further, the cathode separators 6 are configured such that the width W₂ of the portion formed outside the light-emitting element forming area 10A is larger than the width W₁ of the portion formed inside the light-emitting element forming area 10A (see FIG. 1).

In this organic EL panel 100, as the widths W₁ and W₂ of the cathode separators 6 on the counterpart forming surface are formed so as to satisfy W₁<W₂ between the inside and the outside of the light-emitting element forming area 10A, the width W₂ of the portion formed on the outside of the common organic layer 5 is larger than the width W₁ of the portion formed on the common organic layer 5, thereby enlarging the junction area with respect to a counterpart forming surface in the portion formed on the outside of the common organic layer 5. Thus, even if the material of the counterpart forming surface is changed at the end part of the cathode separator 6, the wide junction area can intensify adhesion, thereby preventing a peel-off.

Further, the end part of the cathode separator 6 is formed to extend to the extracting terminal 4, thereby the upper electrode line 2 can be securely insulate-segmented from the inside of the light-emitting element forming area 10A to the extracting terminal 4 outside the light-emitting element forming area 10A, conduction between neighboring upper electrode lines 2 can be prevented, thus electrode wire selection accuracy can be improved when driving the organic EL element 10.

A cathode separator with different widths between the inside and the outside of the light-emitting element forming area 10 A, can be formed by using a mask pattern which is used for forming the cathode separator 6 and can be changed in the width. Also, as shown in FIG. 2, the cathode separator 6 with partially different widths can be formed by changing the tapered angle of a lateral tapered surface 6S as well.

That is, when the lateral part of the cathode separator 6 is formed so as to have a downward tapered surface 6S, the tapered angle of the tapered surface 6S with respect to verticality is formed such that the angle of the portion formed outside the light-emitting element forming area 10A (∠β: see FIG. 2(b)) is smaller than the angle of the portion formed within the light-emitting element forming area 10 (∠α: see FIG. 2(a)). Thus, the width W₁ on the counterpart forming surface can be formed comparatively large at the portion where the tapered angle ∠β is small, while the width W₂ on the counterpart forming surface can be formed comparatively small at the portion where the tapered angle ∠β is large.

The extracting terminal 4 includes light reflective material and the cathode separator 6 is formed such that the lateral part covers the side edge of the terminal 4 as shown in FIG. 2(b). In the example shown in FIG. 2(b), a film 4a composed of light reflective material is formed on the surface of the extracting terminal 4, and the lateral part of the cathode separator 6 is configured to overlap the film 4a composed of the light reflective material in the outside of the light-emitting element forming area 10A. Thus, when forming the cathode separator 6 with light hardening resin, etc., irradiated light is reflected by the film 4a and the hardening speed at the upper lateral part comes close to the hardening speed at the lower lateral part, and the tapered angle ∠β generated by this difference of hardening speed can be reduced.

As shown in FIG. 3(a), when the common organic layer 5 is formed so as to cover the upper surface of the lower electrode line 2, the upper electrode line 3 and the organic layer 11 including a light-emitting layer are laminated on the lower electrode line 2 via the common organic layer 5. As such, the upper surface of the lower electrode line 2, which is formed by ITO, etc., is smoothed by the common organic layer 5, which is formed so as to have a given thickness. Since the organic layer 11 and the upper electrode line 3 are laminated in turn on the smoothed common organic layer 5 as an under layer, the film thickness of the organic layer 11 and the upper electrode line 3 in the organic EL element 10 can be uniformed. Thus, the occurrence of the leak within the organic EL element 10 can be suppressed, while the light emitting property of the organic EL element 10 can be improved.

Further, when the common organic layer 5 is formed so as to cover the upper surface of the lower electrode line 2, an insulating film conventionally covering the side edge of the lower electrode line 2 can be removed. When forming the insulating film, the effective area as an electron injection-electrode of the lower electrode line 2 has been narrowed due to the aperture of the insulating film. By removing the insulating film, the light emitting part of the organic EL element 10 can be formed on the overall lower electrode line 2, and thus the aperture ratio of the organic EL element 10 can be improved. Thereby, the organic EL panel 100 with low-power and high-brightness can be obtained.

Further, as shown in FIG. 3(b), the common organic layer 5 covers the upper surface of the lower electrode line 2 as described above, while the common organic layer 5 can be taper-formed so as to cover the end edge of the extracting terminal 4 connected to the upper electrode line 3 such that a tapered surface is directed upward (see 5T in the drawing). As such, since the common organic layer 5 covers and smoothes the edge part of the extracting terminal 4, the upper electrode line 3, which is connected to the extracting terminal 4 so as to cover it, can be prevented from being cut off by the edge part of the terminal 4.

Next, a method of manufacturing the organic EL panel according to an embodiment of the present invention is described. Here, an example of forming the common organic layer 5 so as to cover the upper surface of the lower electrode line 2 is described. The main manufacturing steps comprise a lower electrode line forming step, an extracting terminal forming step, a common organic layer forming step, a cathode separator forming step, an organic layer forming step, and an upper electrode line forming step. Symbols in FIGS. 1 to 3 are used in the description.

The lower electrode line forming step is a step of stripe-forming a plurality of lower electrode lines 2 on the substrate 1. When taking light from the substrate 1 side, the substrate 1 is formed as a glass substrate, and the lower electrode line 2 is formed as a transparent-electrode such as an ITO, etc. The material of the lower electrode line is film-formed on the substrate 1, and stripe-patterned in a photolithographic step, thus the lower electrode line 2 can be formed.

The extracting terminal forming step is a step of forming a plurality of the extracting terminals 4 electrically connected to the upper electrode lines 3 at the outside of the light-emitting element forming area 10A on the substrate 1. The extracting terminal 4 is formed by patterning terminal material film-formed on the extracting terminal forming area including a position where the end part of the upper electrode line 3, which is preliminarily defined, is formed. The extracting terminal forming step can be performed along with the lower electrode line forming step. In this case, the lower electrode line material is film-formed on both a light-emitting element forming area and an extracting terminal forming area, and the material with lower electrical resistance than the lower electrode line material is film-formed on the extracting terminal forming area, thus the lower electrode line 2 and the extracting terminal 4 are concurrently patterned. As low resistance materials included in the extracting terminal 4, Cr, Al, and Ag can be used Cr, Al, and Ag are effective in that light-reflective material is included in the extracting terminal 4.

The common organic layer forming step is a step of forming the common organic layer 5 so as to cover at least the overall lower electrode line 2 within the light-emitting element forming area 10A. The common organic layer 5 is formed after the lower electrode line 2 and the extracting terminal 4 are patterned, more specifically, the common organic layer 5 is film-formed in the area which covers the light-emitting element forming area 10A and the area covering the end part of the extracting terminal 4 which is formed outside the light-emitting element forming area 10A. The film forming can adopt either one of wet-type process and dry-type process. As the material of the common organic layer 5, high-polymer material or high-polymer material including low-polymer material can be used. Polyalkylthiophene derivative, polyaniline derivative, triphenylamine, sol-gel film of inorganic compound, organic compound film including Lewis acid, conductive polymer and so forth, can be used. The materials capable of withstanding even a later photolithographic step of forming the cathode separator 6 are suited.

The cathode separator forming step stripe-forms the cathode separators 6 insulate-segmenting the upper electrode lines 3 so as to cross the lower electrode lines 2 on the common organic layer 5 within the light-emitting element forming area 10A such that the end part extends to the extracting terminal 4. The lateral face of the cathode separator 6 has a downward tapered surface 6S, and the tapered angle of the tapered surface 6S with respect to verticality is arranged such that the angle ∠β of the portion formed at the outside of the light-emitting element forming area 10A is smaller than the angle ∠α of the portion formed in the light-emitting element forming area 10A. As the materials of the cathode separator 6, insulating materials such as resist material, polyimide and so forth, can be used.

The cathode separator 6 forms cathode separator material on the common organic layer 5 and the neighboring areas where the common organic layer 5 is not formed, and then is patterned using the photolithographic step. More specifically, the cathode separators 6 can be formed by applying negative-type photopolymer to the common organic layer 5 and the neighboring areas where the common organic layer 5 is not formed using spin coating, exposing it using a photomask, and developing it. In order to have the inverted trapezoid as the cross-sectional shape of the cathode separator 6, the generation of speed difference is utilized in development due to the difference in ultra violet ray exposure amount in the thickness direction. With the exposure only from the upper side of the cathode separator 6, the development speed is slowed down at the lower lateral part, thereby reducing the width compared to the upper lateral part where the development speed is comparatively high. The inverted trapezoid shape includes T-shape, wherein the upper surface of the cathode separator 6 has a larger width than the width of counterpart forming surface. The tapered surface 6S of the cathode separator 6 may be a flat surface, a slightly curved surface, or a bent surface for forming the T-shape.

In the portion of the cathode separator 6 extending between the extracting terminals 4, the lateral part is formed so as to cover the side edge of the extracting terminals 4, thus the ultra violet ray in exposure is reflected by the light reflective material in the extracting terminals 4, thereby increasing the exposure amount at the lower lateral part. Thus, the difference in exposure amount along the thickness direction is reduced compared to the case of no reflection at the extracting terminals 4, thereby suppressing the formation of a tapered angle, which is generated due to the speed difference in development. As such, the aforementioned difference can be formed between the tapered angle ∠α and ∠β.

More specifically, when comparing the extracting terminals 4 formed by laminating ITO and various types of light reflective materials, Table 1 shows the widths and the angles of the cathode separator for each case, wherein Al (embodiment 1) or Cr (embodiment 2) is used as the light reflective material, or only ITO (comparative example) is used.

TABLE 1

| | | width of the cathode | | | | |
|---|---|---|---|---|---|---|
| | | separator | | | | |
| | | within | outside | | | |
| | | light- | light- | | | |
| | | emitting | emitting | tapered angle | | |
| | light | element | element | of cathode | | |
| | reflective | forming | forming | separatorcbn | | peeling |
| | material | area 10A | area 10A | α | β | test |
| Emb. 1 | Al | 10.0 | 11.2 | 35 | 26 | ○ |
| Emb. 2 | Cr | 10.0 | 11.2 | 35 | 26 | ○ |
| compar- | none | 10.0 | 10.0 | 35 | 31 | Δ |
| ative | | | | | | |
| example | | | | | | |

In a peeling test, an extracting terminal was cut out vertically and horizontally at 11 positions with a pitch of 1 mm respectively and a total of 100 cells were prepared. Adherence of the film was evaluated by applying a mending tape to the cells then peeling off the tape, and counting the number of cells which could not be peeled off. As shown in the embodiments 1 and 2, by using the extracting terminal 4 employing light reflective materials such as Al, Cr, and so forth, the width of the cathode separator is increased and the tapered angle of the cathode separator is reduced as well With the structure described above, the peel-off of the cathode separator can be prevented. In addition to the aforementioned embodiment wherein the light reflective material is used for the extracting terminal 4, the width or the angle of the cathode separator can be adjusted by defining the conditions of the material, the temperature and the exposure amount, and so forth concerning the cathode separator.

The organic layer forming step is a step of laminating the organic layer 11 including the light-emitting layer on the common organic layer 5 covering the lower electrode line 2. The organic layer 11 is an organic EL medium layer including the light-emitting layer, and is formed on the common organic layer 5 covering the lower electrode line 2. This organic layer 11 may be the light-emitting layer alone, or may be the light-emitting layer added by various types of functional layers for supplying an electron and a hole to the light-emitting layer (for example, an electron injection-transport layer, a hole injection-transport layer, a hole-electron block layer, hole-electron buffer layer, etc). When color-coding is implemented for each color using the light-emitting layer and other functional layers for the purpose of colorization, a mask having an opening corresponding to the light-emitting elements with the same color is used, and film forming is implemented for each color by changing the mask or displacing the position. The film forming for each layer of the organic layer 11 can be implemented by using various types of film-forming technologies such as vacuum based deposition, printing and so forth.

Disclosed hereinafter is an example of forming the organic layer 11 in a situation where the lower electrode line 2 functions as an anode while the upper electrode line 3 functions as a cathode.

For example, NPB (N,N-di(naphtalence)-N,N-dipheneyl-benzidene) is film-formed on the organic layer 5 as a hole transport layer. This hole transport layer has a function of transporting a hole injected from the lower electrode line 2 to the light-emitting layer. This hole transport layer may have a lamination of only one layer or may have a lamination of two or more layers. Further, the hole transport layer may be film-formed not only by a single material, but a single layer may be formed by a plurality of materials, or a host material with high electrical charge transport ability may be doped with a guest material with high electric charge donating (acceptance) property.

Next, the light-emitting layer is film-formed on the hole transport layer. As an example, light-emitting layers of Red (R), Green (G) and Blue (B) are film-formed by a resistive heating deposition method on each film-forming area by using a color changing mask. To create a red color (R), an organic material emitting a red color such as styryl dye is used, the styryl dye including DCM1 (4-(dicyanomethylene)-2-methyl-6-(4′-dimethylaminostyryl)-4H-pyran) and so forth. To create a green color (G), an organic material emitting a green color such as almino-quinolinol complex (Alq₃), etc.is used. To create a blue color (B), an organic material emitting a blue color such as distyryl derivative, triazolederivative, etc. is used. Other materials and a layer structure of host-guest system may be used, and a fluorescence material or a phosphorescence emission material may be used for the light emitting system.

An electron transport layer film-formed on the light-emitting layer is film-formed on the basis of various film forming methods such as resistive heating deposition method, etc.by using various materials, for example, such as almino-quinolinol complex (Alq3), etc. The electron transport layer has a function of transporting the electrons injected from the upper electrode line 3 to the light-emitting layer. This electron transport layer may have a lamination of only one layer or may have a multilayer structure having a lamination of two or more layers. Further, the electron transport layer may be film-formed not only by a single material, but a single layer may be formed by a plurality of materials, or a host material with high electrical charge transport ability may be doped with a guest material with high electric charge donating (acceptance) property.

The upper electrode line forming step is a step of forming the upper electrode line 3 such that the end part is connected to the extracting terminal 4 by film-forming the upper electrode line material on the organic layer 11 via the cathode separator 6 so as to cross the lower electrode line 2. In this step, the upper electrode line material is film-formed on the organic layer 11 after the organic layer 11 is film formed. At this timing, the cathode separator 6 functions as a shadow mask, and the stripe-patterned upper electrode lines 3 are formed between the cathode separators 6. Since the cathode separators 6 are formed extending to the side of the extracting terminals 4, the end parts of the plurality of the stripe-shaped upper electrode line 3 can be connected to the extracting terminals 4.

When the upper electrode line 3 functions as a cathode, the material with lower work function than an anode is used in order to have an electron injection function. For example, when ITO is used as the anode, Aluminum (Al) or Magnesium alloy (Mg—Ag) are preferably used. However, since Al has low electron injection ability, an electron injection layer such as LiF is preferably provided between Al and an electron transport layer.

Following to the above-mentioned each step, a sealing step of shutting off the light-emitting element forming area 10A from the ambient outside air, a mounting step of connecting a driving unit to the terminal part of the lower electrode line 2 and the extracting terminal 4 connected to the upper electrode line 2, and an inspection step and so forth are implemented. The organic EL panel 100 configured as described above can be driven by a passive drive style, for example, the lower electrode lines 2 are driven as data lines while the upper electrode lines 3 are driven as scanning lines.

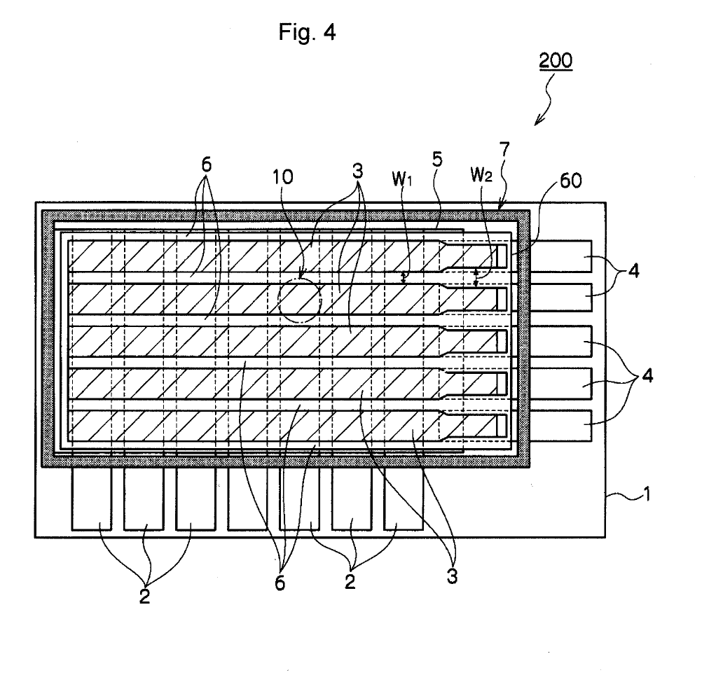

FIG. 4 shows a variation of the organic EL panel according to the embodiment of the present invention. The same symbols are applied to the same parts as the embodiment shown in FIG. 1, and the duplicate description are omitted. In this example, neighboring cathode separators 6 formed between the extracting terminals 4 are connected to each other, and a connecting cathode separator 60 is provided so as to connect these neighboring cathode separators 6. According to this configuration, a segment wall defined by the cathode separators 6 and the connecting cathode separator 60 can be formed on the inner side of an adhesive coating area 7 for joining the substrate 1 and a sealing substrate (not shown in the drawing). As such, when seal-bonding is applied, the segment wall can prevent the adhesive agent layer from entering the light-emitting element area, and thereby the adhesive coating area 7 can be arranged near the light-emitting element forming area, thus, the light-emitting area can be broaden with respect to the area of the substrate 1, and thereby the effective light-emitting area in the panel can be expanded.

1. An organic EL panel forming a plurality of light-emitting elements on a substrate, a single organic EL element being a light-emitting element, said organic EL panel comprising:
a plurality of lower electrode lines stripe-formed on said substrate;
a plurality of upper electrode lines stripe-formed so as to cross said lower electrode lines;
an organic EL element laminating an organic layer including a light-emitting layer between said lower electrode lines and said upper electrode lines in the crossing part of said lower electrode lines and said upper electrode lines;
a plurality of extracting terminals electrically connected to said respective upper electrode lines and formed outside a light-emitting element forming area on which the plurality of said light-emitting elements are formed on said substrate;
a common organic layer formed so as to cover at least overall side edges of said lower electrode lines within said light-emitting element forming area; and
a cathode separator stripe-formed on said common organic layer within said light-emitting element forming area so as to insulate-segment said upper electrode lines with an end part extending to said extracting terminals; wherein
said cathode separator is arranged such that a width in a portion of a counterpart forming area formed outside said light-emitting element forming area is larger than a width in a portion of a counterpart forming area formed inside said light-emitting element forming area.

2. The organic EL panel according to claim 1, wherein said cathode separator includes a lateral face having a downward tapered surface, and a tapered angle of said tapered surface with respect to verticality is arranged such that an angle of the portion formed outside said light-emitting element forming area is smaller than an angle of the portion formed within said light-emitting element forming area.

3. The organic EL panel according to claim 2, wherein said extracting terminals include a light reflective material, and a side part of said cathode separator is formed so as to cover a side edge of said extracting terminals.

4. The organic EL panel according to claim 1, wherein said common organic layer covers an upper surface of said lower electrode lines and taper-covers an end edge of said extracting terminals connected to said upper electrode lines such that a tapered surface of said cathode separator is directed upward.

5. The organic EL panel according to claim 1, wherein neighboring cathode separators formed between said extracting terminals are connected to each other.

6. A method of manufacturing an organic EL panel forming a plurality of light-emitting elements on a substrate, a single organic EL element being a light-emitting element, the method comprising:
forming a plurality of stripe-shaped lower electrode lines on said substrate;
forming a plurality of extracting terminals electrically connected to upper electrode lines on an outside of a light-emitting element forming area on which a plurality of said light-emitting elements on said substrate are formed;
forming a common organic layer so as to cover all of said lower electrode lines within said light-emitting element forming area;
stripe-forming a cathode separator insulate-segmenting said upper electrode lines so as to cross said lower electrode lines on said common organic layer within said light-emitting element forming area with an end part extending to said extracting terminals;
forming an organic layer laminating an organic layer including a light-emitting layer on said common organic layer covering said lower electrode lines; and
forming upper electrode lines so as to cross said lower electrode lines with the end part connected to said extracting terminals by film-forming a material of said upper electrode lines on said organic layer via said cathode separator; wherein
in the step of forming said cathode separator, a lateral face of said cathode separator has a downward tapered surface, and a tapered angle of said tapered surface with respect to verticality is arranged such that an angle of a portion formed outside the light-emitting element forming area is smaller than an angle of a portion formed within the light-emitting element forming area.

7. The method of manufacturing an organic EL panel according to claim 6, wherein said extracting terminal includes a light reflective material, and in the forming said cathode separator, a side part of said cathode separator is formed so as to cover a side edge of said extracting terminals.

8. The method of manufacturing an organic EL panel according to claim 6, wherein in the forming said common organic layer, said common organic layer is formed so as to cover an end edge of the extracting terminal connected to the upper electrode line such that the tapered surface is directed upward.

9. The organic EL panel according to claim 2, wherein said common organic layer covers an upper surface of said lower electrode lines and taper-covers an end edge of said extracting terminals connected to said upper electrode lines such that a tapered surface of said cathode separator is directed upward.

10. The organic EL panel according to claim 3, wherein said common organic layer covers said upper surface of said lower electrode lines and taper-covers the end edge of said extracting terminals connected to said upper electrode lines such that the tapered surface is directed upward.

11. The organic EL panel according to claim 2, wherein neighboring cathode separators formed between said extracting terminals are connected to each other.

12. The organic EL panel according to claim 3, wherein neighboring cathode separators formed between said extracting terminals are connected to each other.

13. The method of manufacturing an organic EL panel according to claim 7, wherein in the forming said common organic layer, said common organic layer is formed so as to cover an end edge of the extracting terminal connected to the upper electrode line such that the tapered surface is directed upward.
